(19) United States
(12) Patent Application Publication
(10) Pub. No.: US 2012/0081824 A1
(43) Pub. Date: Apr. 5, 2012

(54) METHOD AND APPARATUS FOR SUB-HARMONIC PROTECTION

(76) Inventors: Krishnaswamy Gururaj Narendra, Winnipeg (CA); David James Fedirchuk, Lle Des Chenes (CA); Mark Charles Poole, Winnipeg (CA)

(21) Appl. No.: 13/248,639

(22) Filed: Sep. 29, 2011

Related U.S. Application Data
(60) Provisional application No. 61/387,529, filed on Sep. 29, 2010.

(51) Int. Cl. H02H 3/26; G01R 19/00

(52) U.S. Cl. 361/86; 324/76.11; 324/157

(57) ABSTRACT

A method and device for detecting damaging sub-harmonic frequencies in a power system, and recording data or initiating protective action. A microprocessor based sub-harmonic protection relay (S-PRO) monitors system voltages and currents from voltage and current transformers on the power system that may be present in the 5 Hz to 25 Hz frequency window. The user of S-PRO has full programming control to select bandwidths of frequencies or specific frequency components of the collected system voltages and currents. S-PRO can be user programmed to either detect the sub-harmonic power quantities and record them for future use in simulations or to initiate protective action. Protective action may include initiating output contact closure on the device to shut down equipment or to initiate corrective actions to prevent damage.

### CROSS REFERENCE TO RELATED APPLICATIONS

This application claims the benefit of and priority from U.S. Provisional Patent Application No. 61/387,529 filed Sep. 29, 2010, which is incorporated herein by reference in its entirety

### FIELD

The present disclosure relates generally to electric power systems. More particularly, the present disclosure relates to sub-harmonic monitoring and protection for power systems.

### BACKGROUND

The goal of a power system is to provide reliable power from sources of generation to customer loads. In the process of providing this power, the operation of the power system can be affected by interaction of various components of the power system that can excite non characteristic sub-harmonics frequency (below 60 Hz or 50 Hz system frequency) voltages and currents.

Normally, power systems operate at 50 or 60 Hz, which results in currents and voltages at this same frequency. Occasionally, system disturbances can occur in which low frequency oscillations in the system voltages and currents can occur. The oscillations can be caused by interactions between control devices such as generator excitation systems, governors or other controllers.

On the other hand, switching devices such as thyristors with their current chopping action can create harmonics on the power system, usually in the range of the 5th to the 13th harmonic.

In some cases, interaction between generation sources such as wind turbines and thermal fossil fuelled generators in operation with transmission line series capacitors can resonate to produce low frequency oscillations in power system quantities in the range of 5 to 40 Hz. These resonances are known in the industry as Sub Synchronous Resonances. If left unchecked, the low frequency quantities can excite mechanical resonances in generator turbine shafts and can cause catastrophic failure of mechanical components.

Excitation of non characteristic sub-harmonic frequency voltages and currents is particularly prevalent on power system locations where Wind generation farms (series of Wind turbines located off shore to produce electrical energy) are located since these generators are typically located far away from load centers and to increase the power flow, series capacitors are normally installed to compensate transmission line reactance. The interaction of the series capacitor with the Wind system can cause un-damped sub-harmonic current oscillations, which can cause serious damage to the Wind turbine controllers and also the conventional generators. The Wind turbine mechanical system interactions (tower-to-blade) can also generate sub-harmonics, which are detrimental to the induction generators, transformers, and may cause resonance at point of common coupling in the electrical grid.

Because of the desire to have renewable energy, the number of wind farm locations is increasing dramatically throughout North America as well as elsewhere in the world. This sub-synchronous effect takes place when the sources of sub-harmonics such as Wind generators excite the sub-harmonic frequencies of the series capacitor and transmission line system. This in turn, can also cause low frequency mechanical resonant forces within the rotor shafts of electrical generators. If allowed to persist, extreme mechanical damage to these generator shafts will occur. Interaction of series capacitors with the wind system in wind farms can cause un-damped sub-harmonic current oscillations. The wind turbine mechanical system (tower to blade) interactions can also generate sub-harmonics. These sub-harmonics can cause serious damage to the wind turbine controllers, induction generators and transformers, and may cause resonance at point of common coupling in the electrical grid.

### SUMMARY

This disclosure relates to a microprocessor based sub-harmonic monitoring and protection Relay (S-PRO) or a device that can monitor and protect the components of an electric power system (such as a three-phase power system) from damage for a condition where sub-harmonic or sub-synchronous frequency components (below 60 Hz or 50 Hz system frequency,) of voltage and current can cause detrimental effects to the entire system in an electrical grid. The S-PRO Relay prevents the damage caused by tripping or isolating such sub-harmonic sources from the rest of the electrical network to secure the electrical grid and assure availability of reliable electric power.

This microprocessor based S-PRO Relay development is aimed for more locations where the sub-synchronous effect is an issue and as such needs to be protected, monitored, and controlled. The S-PRO Sub-Harmonic Protection Relay allows monitoring of, indication of, recording of, and protection from, uncontrolled sub-harmonics ensuring a reliable operation of a power grid.

The motivation for this innovation is to provide a device that can be installed on a power system to monitor (continuously or intermittently) the power system for these potentially damaging sub-harmonic quantities. The S-PRO monitors system voltages, currents, or both from voltage and current transformers on the power system that may be present in the 5 Hz to 25 Hz frequency window. The user of S-PRO has full programming control to select bandwidths of frequencies or specific frequency components of the collected system voltages and currents. S-PRO can be user programmed to either just detect the sub-harmonic power quantities and record them for future use in simulations or to initiate protective action by initiating output contact closure on the device that can be used to shut down equipment or to initiate corrective actions to prevent damage.

The disclosed system and methods provide sub-harmonic protection for transmission lines at any voltage level, particularly those with serial compensation and interconnected with wind farms. The disclosed systems and methods provide control, automation, metering, monitoring, fault oscillography, dynamic swing recording, and event logging with advanced communications.

S-PRO addresses problems that occur when wind farms are in communication with a power system. However, S-PRO may be applied to power generation systems other than wind farms, and may be useful outside of power generation, in any system wherein sub-harmonics cause problems.

The disclosed apparatus, system and methods provide monitoring and protection of uncontrolled sub-harmonics ensuring a reliable operation and protection of the power grid and equipment. The disclosed apparatus, system and method provide real time processing of voltage and current signals, comprehensive sub-harmonic protection, with sub-harmonic monitoring from 5 Hz to 40 Hz (with a resolution of 1 Hz), with 2 sub-harmonic detectors for each 3 phase analog quantities. Each detector is capable of alarming or tripping as configured by the by the user. An “Operations/Minute” trigger monitors the sub-harmonic level to cope up with the statistical nature of the Wind turbine operations and availability. In addition a total of 4 sets of configurable 3 phase current summation virtual channels are also monitored. These virtual channels allow two sets of 3 phase currents to be added together to form a line current suitable for ring bus configuration. Each of the summated virtual channels also has two sub-harmonic detectors associated with them.

In an embodiment disclosed, the system takes in current and voltages from the power system elements such as transmission lines and generators. In an embodiment disclosed, four 3-phase sets of currents plus 2 sets of 3-phase to neutral voltages are utilized. In addition a total of 4 sets of configurable 3-phase current summation virtual channels may also be monitored. These virtual channels allow 2 sets of 3-phase currents to be added together to form a line current suitable for ring bus configuration.

In an embodiment disclosed, the system can detect low frequency components on the ac input currents and voltages in the range of 5 to 40 Hz. This detection of specific frequencies or bands of frequencies and magnitudes are user selectable. Once detected, these quantities can be set to provide the user with indications, alarms or can be set to provide output contact closures. In addition, the detection of these low frequency current and voltage components can also be set to initiate recordings of these quantities for further system analysis.

In an embodiment disclosed, in order to detect low frequency components in elements such as lines in ring bus conditions, the system has the ability to sum two sets of currents. This summation can then be user set to detect low frequency components such as lines.

In an embodiment disclosed, in addition to the low frequency recording capability, the system can provide fault recording with harmonics up to the 25th harmonic for the input currents and voltages.

|n an embodiment disclosed, the methods, system, and apparatus may provide, as examples, but not limited to the following protection functions for abnormal power system conditions:

Definite time delay overcurrent (Device 50LS) functions on each of the current inputs.

Definite time delay undervoltage (Device 27) function for the Main voltage input.

Definite time delay undervoltage (Device 27) function for the Aux. voltage input.

Definite time delay overvoltage (Device 59) function for the Main voltage input.

Definite time delay overvoltage (Device 59) function for the Aux voltage input.

Sub-Harmonic detector and level (two of them) for input current 1

Sub-Harmonic detector and level (two of them) for input current 2

Sub-Harmonic detector and level (two of them) for input current 3

Sub-Harmonic detector and level (two of them) for input current 4

Sub-Harmonic detector and level (two of them) for summation current 1

Sub-Harmonic detector and level (two of them) for summation current 2

Sub-Harmonic detector and level (two of them) for summation current 3

Sub-Harmonic detector and level (two of them) for summation current 4

Sub-Harmonic detector and level (two of them) for the Main Voltage

Sub-Harmonic detector and level (two of them) for the Aux Voltage

ProLogic™ functions (twenty four of them) to combine protection functions.

As used herein. Device 27, 50LS, 59, etc. refer to standard device numbers used in protection systems, known to one skilled in the art, referencing ANSI/IEEE Standard C37.2 Standard Electrical Power System Device Function Numbers, Acronyms and Contact Designations.

In an embodiment disclosed, each of the current input quantities and current summation channels can be set to initiate its definite time overcurrent device 50LS. In an embodiment disclosed, the overcurrent device may have a setting range of 0.1 to 50 A rms secondary.

In an embodiment disclosed, the voltages on the Main or Aux inputs can have a definite time delay under voltage function applied device 27.

In an embodiment disclosed the voltages on the Main or Aux inputs can have a definite time delay over voltage function applied device 59.

In an embodiment disclosed, each AC voltage and current input has 2 definite time delay level detectors. Each of the summated virtual channels also has 2 sub-harmonic detectors associated with them. These detectors can be set to close a contact, provide an alarm or trigger a recording. The detectors can be set to respond to frequencies in the 5-40 Hz range.

It is an object of the present disclosure to obviate or mitigate at least one disadvantage of operating a system wherein sub-harmonic disturbances may cause damage or other problems.

In a first aspect, the present disclosure provides a Microprocessor based sub-harmonic protection relay (S-PRO) to detect sub-harmonics (below 60 Hz or 50 Hz system nominal frequency) in the voltage, current and derived summated current signals in electrical power systems including wind generations.

In a further aspect, the present disclosure provides a method of using data collected from a sub-harmonic protection relay to capture and store sub-harmonics for further system studies and analysis.

In a further aspect, the present disclosure provides a method to use data from a sub-harmonic protection relay to ALARM, provide relay contact closure (TRIP), or both, to prevent power system component damage because of sub synchronous resonance caused due to sub-harmonic power system voltage, current, or both quantities.

In a further aspect, the present disclosure provides a method of controlling an electrical protection relay on an electrical power system including

selecting a threshold value for an electrical property of the power system;

detecting an observed value of the electrical property;

comparing the observed value to the threshold value; and

performing a protective action if the observed value exceeds the threshold value.

In an embodiment of the disclosure, the electrical property is voltage.

In an embodiment of the disclosure, the electrical property is current.

In an embodiment of the disclosure, the protective action includes changing the state of the electrical protection relay.

In an embodiment of the disclosure, the protective action includes changing the state of the electrical protection relay to interrupt communication between components of the power system.

In an embodiment of the disclosure, the protective action includes producing a user-perceivable signal.

In an embodiment of the disclosure, the threshold value is sub-harmonic.

In an embodiment of the disclosure, the observed value includes a frequency component.

In an embodiment of the disclosure, the method includes selecting a low threshold value for an electrical property of the power system, the low threshold value less than the threshold value; comparing the observed value to the low threshold value; and performing a protective action if the observed value exceeds the low threshold value greater than a selected number of events per unit of time.

In an embodiment of the disclosure, the observed value includes a frequency component about 5 Hz and about 25 Hz.

In an embodiment of the disclosure, the method includes recording the threshold value.

In an embodiment of the disclosure, the method includes recording the observed value.

In an embodiment of the disclosure, the electrical power system includes a turbine.

In a further aspect, the present disclosure provides a microprocessor-based detector sensitive to changes in an electrical property of an electrical power system.

In an embodiment of the disclosure, the electrical property is voltage.

In an embodiment of the disclosure, the electrical property is current.

In an embodiment of the disclosure, the electrical property includes a frequency component.

In an embodiment of the disclosure, the electrical property includes a frequency component between about 5 Hz and about 25 Hz.

In an embodiment of the disclosure, the electrical property includes a frequency component having sub-harmonic values.

In an embodiment of the disclosure, the electrical power system includes a turbine.

Other aspects and features of the present disclosure will become apparent to those ordinarily skilled in the art upon review of the following description of specific embodiments in conjunction with the accompanying figures.

### BRIEF DESCRIPTION OF THE DRAWINGS

Embodiments of the present disclosure will now be described, by way of example only, with reference to the attached Figures.

FIG. 1 is a block diagram of a microprocessor based sub-harmonic protection relay in accordance with the present disclosure;

FIG. 2 is the sub-harmonic measurement and detection logic in accordance with the present disclosure;

FIG. 3 is an example plot of detected sub-harmonic levels as a function of frequency in accordance with the present disclosure;

FIG. 4 is a protection and control function diagram in accordance with the present disclosure; and

FIG. 5 is a schematic for connecting a device of the present disclosure to an AC power system.

### DETAILED DESCRIPTION

Microprocessor Based Sub-Harmonic Protection Relay (S-Pro)

Generally, the present disclosure provides a method, system and apparatus for sub-harmonic monitoring and protection. As used herein. S-PRO refers to the method, system, and apparatus for sub-harmonic monitoring and protection disclosed herein.

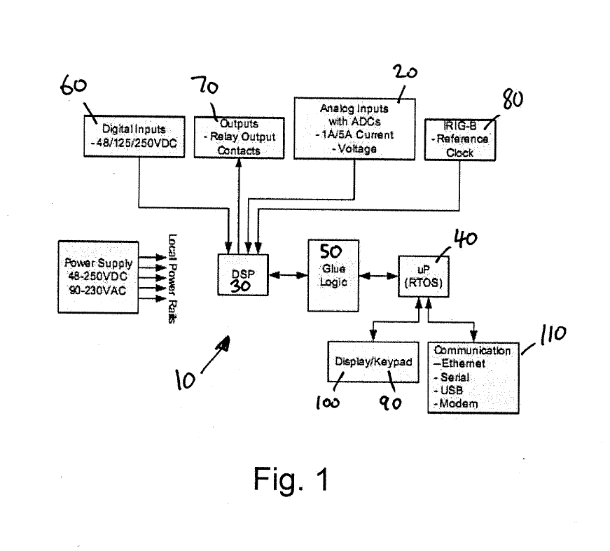

FIG. 1 is a block diagram of an embodiment of a micro processor based S-PRO relay 10. The S-PRO relay 10 is a microprocessor based device that can receive four sets of power system inputs 20, for example alternating current three phase currents and two sets of three phase voltages from current or voltage transformers, or both. Two sets of level detectors can be set for each input quantity to detect specific frequency components in the 5 Hz to 25 Hz range or to detect ranges of frequencies over this range.

The S-PRO relay 10 has the ability to sum quantities from, for example, two current transformers on a ring bus that might represent the current as seen on a particular power line, and then apply the level detectors to these summated quantities. The S-PRO relay 10 also has recording triggering capability to alarm or take action for cyclical sub-harmonic quantities that may be oscillating just below the tripping levels. Sub-harmonic data is collected as it occurs even if it is on the verge of being a problem. User setting of the pickup levels and the time delays of the detectors and action that is taken, is fully selectable. For completeness, the S-PRO relay 10 also has the ability to collect and store fault and harmonic voltage and current quantities. The S-PRO relay 10 samples the inputs 20 at 96 samples per cycle (60 Hz or 50 Hz system), so with its and aliasing filtering, up to the 25th harmonic on the inputs 20 are made available. The 96 samples per cycle sampling capability allows fault recording, dynamic swing recording, and event logging (1 ms). The S-PRO relay 10 also allows metering functions on each input 20 connection. In this way, a complete synopsis of power system data is collected for further study or analysis by the user.

Detector and event operations are time tagged and presented in a log. IRIG-B time stamping 80 and sample synchronization is possible through connection of the S-PRO relay 10 to a time clock satellite receiver (for example through a BNC connector). All information and data collected can be retrieved remotely, for example via a telecommunications network, or locally for example via a connection to a local interface at the S-PRO relay 10, for example a universal serial bus (USB) connection.

The S-PRO relay 10 may include two processors: a digital signal processor (DSP) 30 and a second microprocessor (μP) 40. The DSP 30 includes time critical processor functions, such as those related to data interpretation, recording, and protective action. The DSP 30 includes real time Fourier transform or recursive Fourier transform (collectively or individually, RFT) functions. The μP 40 includes time-insensitive functions such as receiving input from a keyboard 90, displaying information on an display 100, or functions related to a network 110. The DSP 30 and the μP 40 communicate through glue logic 50.

The S-PRO relay 10 may include 5 A or 1 A analog current inputs 20. Where The S-PRO relay 10 is in communication with a high-power system such as a high-power transmission line (not shown), input may be stepped down to either 5 A or 1 A via analog digital converter (ADC). Similarly, voltage inputs may be stepped down from for example, 110 kV or 320 kV, stepped down to 100V. Digital inputs 60 may also be included for provision of input from other devices rather than from analog sources. Outputs 70 allow protective actions to be taken by the DSP directly (for example when the state of a relay must be changed).

The S-PRO relay 10 provides a number of sub-harmonic detectors associated to each of the three phase AC analog phase currents and voltages. In an embodiment, two detectors are provided for each three phase analog quantity. Each detector is capable of alarming or tripping as configured by the by the user, and each detector may have a different delay value. An “Operations/Minute” trigger monitors the sub-harmonic level to cope with the statistical nature of the Wind turbine operations and availability. Voltage may be monitored, for example, through IEEE devices 27 and 59. Current may be monitored, for example, through IEEE device 50LS.

Four sets of configurable three phase current summation virtual channels are also monitored (for example through IEEE device 50LS). These virtual channels allow two sets of three phase currents to be added together to form a line current suitable for ring bus configuration. Each of the summated virtual channels also has two sub-harmonic detectors associated with them.

The S-PRO relay 10 may also include enhanced user configurable DNP mapping list and user-configurable logic. An example of user-configurable logic is ProLogic™ with 24 control logic statements per setting group and five inputs per ProLogic™ statement. Eight setting groups are available, with 16 group logic statements per setting group and five inputs per group logic statement.

The S-PRO relay 10 may be built on a contemporary new substation hardened hardware platform. The S-PRO relay 10 may be operated through an interface having intuitive relay settings and record analysis software (for example through Windows™ 2000 or Windows™ XP or similar operating systems). The S-PRO relay 10 may be operated through intuitive relay control panel software (f) r example through Windows 2000 or Windows XP) to provide full local or remote access.

The S-PRO relay 10 may be present on a system that supports enhanced DNP3 SCADA communication protocol including user-selectable point lists, class support and multiple master station support. The S-PRO relay 10 may be present on a system that supports Modbus™ supervisory control and data acquisition (SCADA) communication protocol. The S-PRO relay 10 may also allow ring bus and breaker-and-a-half current sub-harmonic detection. Other features in the S-PRO relay 10 based system may include serial communication ports, multiple (for example 30) virtual inputs for local and remote control, and an internal modem.

The S-PRO relay 10 is a microprocessor based device that can take in four sets power system alternating current 3-phase currents and two sets of 3-phase voltages from current and voltage transformers. Two sets of level detectors can be set for each input quantity to detect specific frequency components in the 5 to 40 Hz range or to detect ranges of frequencies over this range. The S-PRO relay 10 also has the ability to sum quantities from say two current transformers on a ring bus that might represent the current as seem on a particular line, and then apply the level detectors to these summated quantities. The S-PRO relay 10 also has recording triggering capability to alarm or take action for cyclical sub-harmonic quantities that may be oscillating just below the tripping levels. The intention here is to collect sub-harmonic data as it occurs even if it is on the verge of being a problem. User setting of the pickup levels and the time delays of the detectors and action that is taken, is fully selectable. For completeness, the S-PRO relay 10 also has the ability to collect and store fault and harmonic voltage and current quantities. S-PRO samples the input quantities at 96 samples per cycle (60 Hz or 50 Hz system), so with its anti-aliasing filtering, up to the 25th harmonic on the input quantities is made available. In this way, a complete synopsis of power system data is collected for further studies by the user. All detector and event operations are time tagged and presented in a log. IRIG-B time synchronization is possible through connection of S-PRO to a time clock satellite receiver. All information and data collected can be retrieved remotely or from the USB on the front of the S-PRO.

Principle of Sub-Harmonic Quantities Measurement and Detection

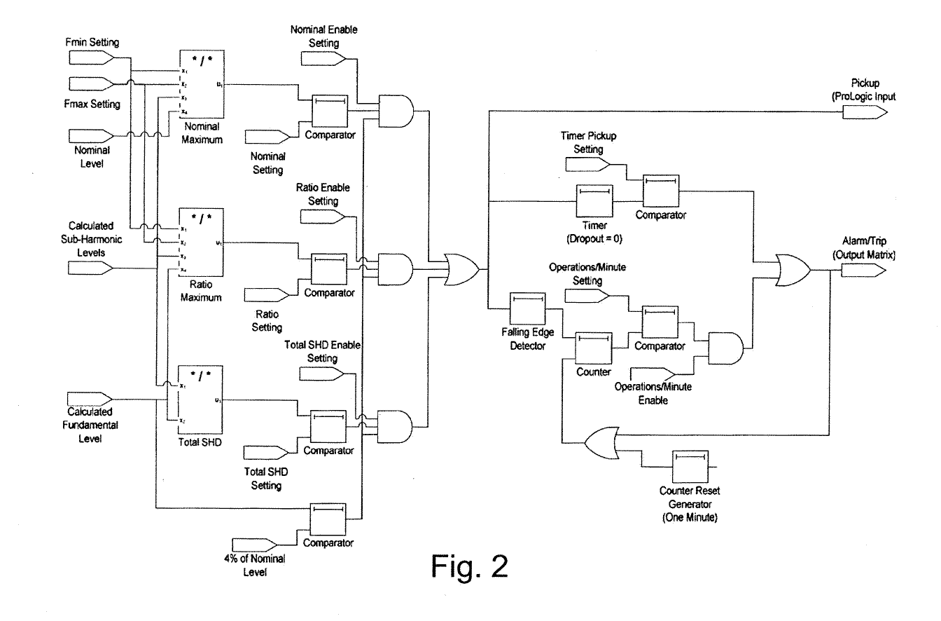

FIG. 2 is a functional logic diagram of an embodiment of the proposed sub-harmonic detection relay. RFT is the principle used in detecting the sub-harmonic(s). The digital data available after the Analog to Digital Conversion for each voltage and current channel is evaluated based on the following algorithm to track the sub-harmonic frequencies in the range between 5 Hz to 25 Hz, with 1 second window. The resolution is 1 Hz (allowing protection of a power grid from sub-harmonic oscillations at the point-of-common-coupling every one second, with additional user configurable delays). The digital RFT will be evaluated in real time for up to all of the 30 channels (4 sets of 3 phase currents, 2 sets of 3 phase voltages, and 4 sets of 3 phase summated currents).

Each detector may have a nominal, fundamental, Total Sub-harmonic Detector (TSHD), and operation per minute setting. A user can set a band or group of sub-harmonic frequencies for Nominal or Ratio detectors. The TSHD will be calculated for the 5 Hz-25 Hz range of sub-harmonics with respect to the fundamental. A special detector tracks the number of times the nominal, fundamental and/or TSHD come and go (falling edge detector). The special detector allows the user to detect non-continuous sub-harmonic occurrences over a one minute period, which cannot be tracked by the other detectors.

Protective action taken by the S-PRO relay 10 may be made through either communication or display output (for example in the case of an alarm), or through other outputs (for example in the case of an alarm or to alter the state of a relay). Where a protective action includes changing the state of a relay, the relay may be moved, either from an open to a closed position, or from a closed to an open position. An alarm may be a useful protective action when for example, responding to levels of sub-harmonic disturbances that are not sufficient to cause immediate or serious damage.

The embodiment depicted may include one or more of the following settings:

TABLE 1
Settings

[Nominal | Ratio | Total SHD | Operations/Minute] Enable Settings true/false, default = false
Fmin Setting: 5 Hz to 25 Hz, 1 Hz step, 5 Hz default
Fmax Setting: 5 Hz to 40 Hz, 1 Hz step, 25 Hz default
Nominal Setting: percent of nominal level from Fmin to Fmax
1% to 200% (1 A/5 A for currents), 1% step, 100% default
1% to 15% (69 V for voltages), 1% step, 5% default
Ratio Setting: ratio of sub harmonic level to fundamental level from Fmin to Fmax
1% to 200% (1 A/5 A for currents), 1% step, 100% default
1% to 15% (69 V for voltages), 1% step, 5% default
Total SHD Setting:
1% to 200% (1 A/5 A for currents), 1% step, 100% default*
1% to 15% (69 V for voltages), 1% step, 5% default
Total SHD = sqrt(sq(5 Hz level) + . . . + sq(40 Hz level))/fundamental level
Timer Pickup Setting: 0.0 to 999.0 seconds, 1.0 second step, 10.0 second default
Operations/Minute Setting: 1 to 999 operations/minute, 1 operation/minute step, 60 operations/minute default

The principle used in detecting the sub-harmonic is known as the Real time Fourier Transform or Recursive Fourier Transform (RFT). The digital data available after the Analog to Digital Conversion for each voltage and current channel is evaluated based on the following algorithm to track the sub-harmonic frequencies in the range between 5 Hz to 40 Hz, with 1 second window. The resolution is 1 Hz. The digital RFT is evaluated in real time for all the input channels (4 sets of 3-phase currents, 2 sets of 3-phase voltages, and 4 sets of 3-phase summated currents). The user can also set a band or group of sub-harmonic frequencies for Nominal or Ratio detectors. The Total sub-harmonic Detector (TSHD) will be calculated for the 5 Hz-40 Hz range of sub-harmonics with respect to the fundamental. There is a special detector used to track the sub-harmonic occurrence in operations/minutes just below the threshold limit, which cannot be tracked by the other two detectors.

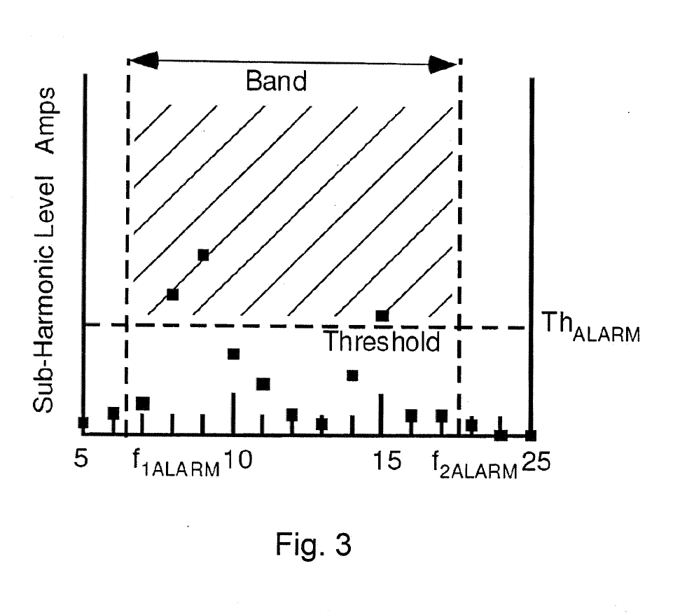

FIG. 3 is an example plot of detected sub-harmonic levels as a function of frequency. The S-PRO relay 10 provides real time processing of voltage and current signals, comprehensive sub-harmonic protection, with sub-harmonic monitoring with a 1 Hz resolution in the range from 5 Hz to 25 Hz in accordance with FIG. 3. A sub-harmonic level value of Th_{ALARM} is indicated in FIG. 3. Th_{ALARM} is a threshold value configured by the user, and an alarm is triggered if the sub-harmonic level of any frequency within the user-selected band (in FIG. 3, between 7 and 17 Hz) above Th_{ALARM} is detected. In FIG. 3, the threshold value has been exceeded at 8, 9, and 15 Hz. Sub-harmonic levels are equivalent to the amplitude of a signal at a given frequency. One example of a threshold value is a given maximum ratio of the calculated sub-harmonic levels to the calculated fundamental level. In FIG. 2, three different conditions are monitored for alarm or other protective actions: nominal maximum, ratio maximum (of calculated sub-harmonic to calculated fundamental levels, and TSHD. The detection limit may be approximately 4% of nominal level.

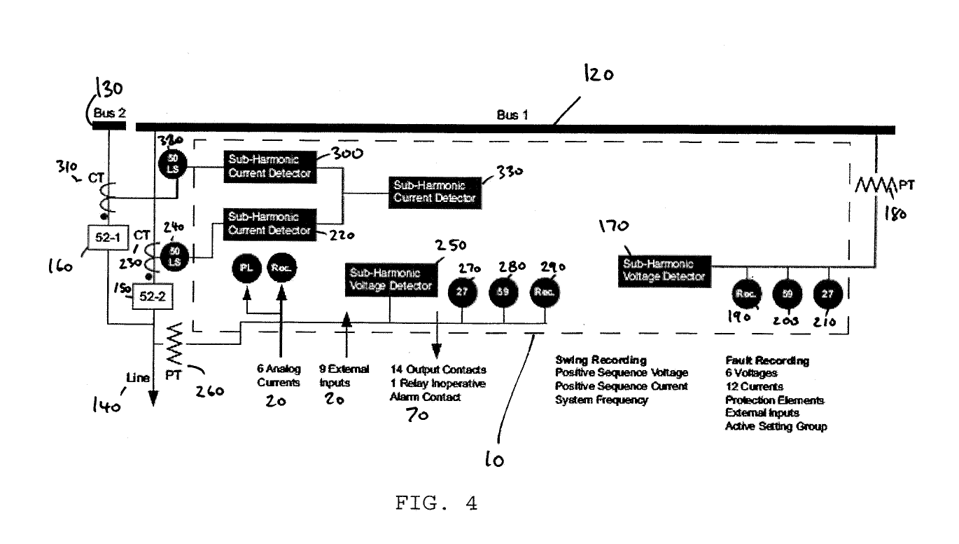

FIG. 4 is an example protection and control function diagram of the present disclosure. The S-PRO relay 10 connects to a first bus 120 and a second bus 130. The first bus 120 is connected to a line 140 via a circuit breaker 150. The second bus 130 is connected to the line 140 via a circuit breaker 160.

A sub-harmonic voltage detector 170 is connected to the first bus 120/line 140 via a transformer 180. Recording, IEEE device 59, and IEEE device 27 are provided as 190, 200, and 210. A sub-harmonic current detector 220 is connected to the first bus 120 via a transformer 230. IEEE device 50LS is provided as 240. A sub-harmonic voltage detector 250 is connected to the line 140 via a transformer 260. IEEE device 27. IEEE device 59, and recording are provided as 270, 280, and 290. A sub-harmonic current detector 300 is connected to the second bus 130/line 140 via a transformer 310. IEEE device 50LS is provided as 320. The information from the sub-harmonic current detector 300 and the sub-harmonic current detector 270 may be summed, logically combined, or both for a sub-harmonic current detector 330.

Additional analog current inputs 20 and external inputs 20 may be received by the S-PRO relay 10. Output contacts, relay contacts, or alarm contacts 70 may be provided.

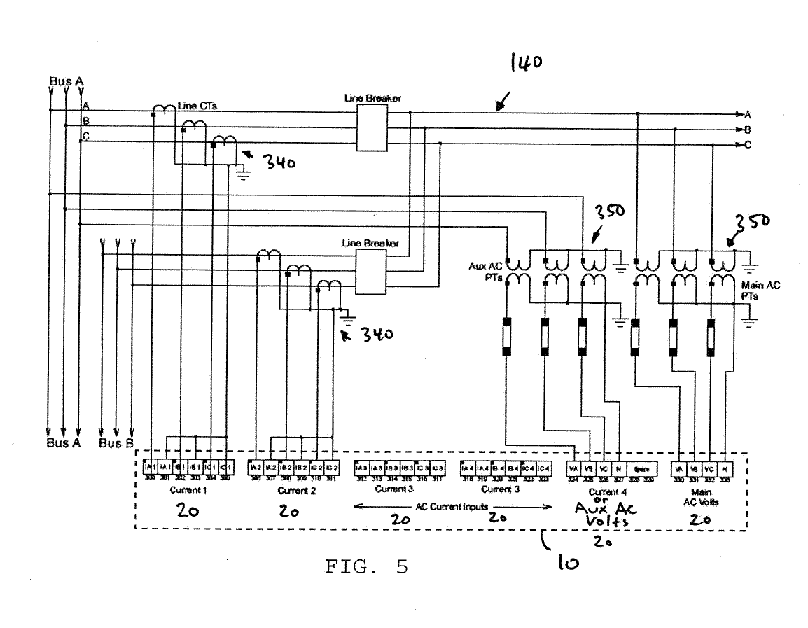

FIG. 5 is an example schematic of connecting a device of the present disclosure to an AC power system.

The S-PRO relay 10 connects to a line 140. Current transformers (CT) 340 step down the line current to inputs 20. Power transformers (PT) 350 step down the line voltage to inputs 20. In this figure, the outputs are not shown.

A method and device for detecting damaging sub-harmonic frequencies in a power system, and recording data or initiating protective action. A microprocessor based sub-harmonic protection relay (S-PRO) monitors system voltages and currents from voltage and current transformers on the power system that may be present in the 5 Hz to 25 Hz frequency window. The user of S-PRO has full programming control to select bandwidths of frequencies or specific frequency components of the collected system voltages and currents. S-PRO can be user programmed to either detect the sub-harmonic power quantities and record them for future use in simulations or to initiate protective action. Protective action may include initiating output contact closure on the device to shut down equipment or to initiate corrective actions to prevent damage.

In the preceding description, for purposes of explanation, numerous details are set forth in order to provide a thorough understanding of the embodiments. However, it will be apparent to one skilled in the art that these specific details are not required. In other instances, well-known electrical structures and circuits are shown in block diagram form in order not to obscure the understanding. For example, specific details are not provided as to whether the embodiments described herein are implemented as a software routine, hardware circuit, firmware, or a combination thereof.

Embodiments of the disclosure can be represented as a computer program product stored in a machine-readable medium (also referred to as a computer-readable medium, a processor-readable medium, or a computer usable medium having a computer-readable program code embodied therein). The machine-readable medium can be any suitable tangible, non-transitory medium, including magnetic, optical, or electrical storage medium including a diskette, compact disk read only memory (CD-ROM), memory device (volatile or non-volatile), or similar storage mechanism. The machine-readable medium can contain various sets of instructions, code sequences, configuration information, or other data, which, when executed, cause a processor to perform steps in a method according to an embodiment of the disclosure. Those of ordinary skill in the art will appreciate that other instructions and operations necessary to implement the described implementations can also be stored on the machine-readable medium. The instructions stored on the machine-readable medium can be executed by a processor or other suitable processing device, and can interface with circuitry to perform the described tasks.

The above-described embodiments are intended to be examples only. Alterations, modifications and variations can be effected to the particular embodiments by those of skill in the art without departing from the scope, which is defined solely by the claims appended hereto.

What is claimed is:

1. A Microprocessor based sub-harmonic protection relay to detect sub-harmonics (below 60 Hz or 50 Hz system nominal frequency) in the voltage, current and derived summated current signals in electrical power systems including wind generation.

2. A method of using data collected from a sub-harmonic protection relay to capture and store sub-harmonics for further system studies and analysis.

3. A method to use data from a sub-harmonic protection relay to ALARM, provide relay contact closure (TRIP), or both, to prevent power system component damage because of sub synchronous resonance caused due to sub-harmonic power system voltage, current, or both quantities.

4. A method of controlling an electrical protection relay on an electrical power system comprising:
selecting a threshold value for an electrical property of the power system;
detecting an observed value of the electrical property;
comparing the observed value to the threshold value; and
performing a protective action if the observed value exceeds the threshold value.

5. The method of claim 4, wherein the electrical property is voltage.

6. The method of claim 4, wherein the electrical property is current.

7. The method of claim 4, wherein the protective action comprises changing the state of the electrical protection relay.

8. The method of claim 7, wherein changing the state of the electrical protection relay interrupts communication between components of the power system.

9. The method of claim 4, wherein the protective action comprises producing a user-perceivable signal.

10. The method of claim 4, wherein the threshold value is sub-harmonic.

11. The method of claim 4, wherein the observed value comprises a frequency component.

12. The method of claim 4, further comprising
selecting a low threshold value for an electrical property of the power system, the low threshold value less than the threshold value;
comparing the observed value to the low threshold value;
performing a protective action if the observed value exceeds the low threshold value greater than a selected number of events per unit of time.

13. The method of claim 11, wherein the frequency component is between about 5 Hz and about 40 Hz.

14. The method of claim 13, wherein the frequency component is between about 5 Hz and about 25 Hz.

15. The method of claim 4, further comprising recording the threshold value.

16. The method of claim 4, further comprising recording the observed value.

17. The method of claim 4, wherein the electrical power system comprises a wind turbine.

18. A microprocessor-based detector sensitive to changes in an electrical property of an electrical power system.

19. The detector of claim 18, wherein the electrical property is voltage.

20. The detector of claim 18, wherein the electrical property is current.

21. The detector of claim 18, wherein the electrical property comprises a frequency component.

22. The detector of claim 21, wherein the frequency component is between about 5 Hz and about 25 Hz.

23. The detector of claim 21, wherein the frequency component comprises sub-harmonic values.

24. The detector of claim 18, wherein the electrical power system comprises a wind turbine.
